(19) United States
(12) Patent Application Publication
(10) Pub. No.: US 2008/0258166 A1
(43) Pub. Date: Oct. 23, 2008

(54) Semiconductor Light Emitting Device and Method for Manufacturing the Same

(76) Inventors: Mitsuhiko Sakai, Kyoto-shi (JP); Shinichi Kohda, Kyoto-shi (JP); Masayuki Sonobe, Kyoto-shi (JP); Ken Nakahara, Kyoto-shi (JP)

Correspondence Address: RABIN & Berdo, PC, 1101 14TH STREET, NW, SUITE 500, WASHINGTON, DC, 20005, US

(21) Appl. No.: 11/596,124

(22) PCT Filed: May 10, 2005
(86) PCT No.: PCT/JP2005/008510

§ 371 Date: Nov. 9, 2006

(30) Foreign Application Priority Data
May 11, 2004 (JP) 2004-140995
Apr. 27, 2005 (JP) 2005-130575

(51) Int. Cl. H01L 33/00

(52) U.S. Cl. 257/99; 257/E33.063

(57) ABSTRACT

There is provided a semiconductor light emitting semiconductor device including an n-side electrode which has a structure capable of stably suppressing the contact resistance between the n-side electrode and a nitride semiconductor layer. Further, there is provided a light emitting device and a manufacturing method wherein an ohmic contact between the n-side electrode and the nitride semiconductor layer can be obtained by a simple manufacturing process, and the n-side electrode has an Au layer on a top surface to facilitate wire bonding. Semiconductor layers (2-8) to form a light emitting layer are laminated on a surface of a substrate (1) made of, for example, a sapphire (Al₂O₃ single crystal) or the like and a p-side electrode (10) is formed on the surface thereof thorough a light transmitting conductive layer (9). An n-side electrode (11) is formed on an exposed surface of an n-type layer (4), exposed by removing a part of the semiconductor layers (4-8) by etching. The n-side electrode includes actually an Al layer (11a) in contact with the n-type layer, a barrier metal layer (11b) and an Au layer (11c).

### FIELD OF THE INVENTION

The present invention relates to a semiconductor light emitting device emitting a blue type light (which means a light having a color band from ultraviolet to yellow), in which a nitride semiconductor is laminated on a substrate, and relates to a method for manufacturing the same. More particularly, the present invention relates to a nitride semiconductor light emitting device which can be formed in a little production manhour and easily, while improving an ohmic contact of an n-side electrode formed on an n-type layer of the nitride semiconductor, and relates to a method for manufacturing the same.

### BACKGROUND OF THE INVENTION

In the prior art, a semiconductor light emitting device emitting a blue type light is formed, for example, on a sapphire substrate by laminating an n-type layer made of GaN or the like, an active layer (light emitting layer) made of a material having a smaller band gap energy than that of the n-type layer and deciding a wavelength of light emitted, for example, such as an InGaN based compound semiconductor (which means that a ratio of In to Ga can be varied variously and the same applies hereinafter), and a p-type layer made of GaN or the like. And a p-side (upper) electrode is formed thereon and an n-side (lower) electrode is formed on an exposed surface of the n-type layer by etching a part of laminated semiconductor layers. A semiconductor layer, having a still larger band gap energy, made of AlGaN based compound (which means that a ratio of Al to Ga can be varied variously and the same applies hereinafter) or the like may be employed on active layer sides of the p-type and n-type layers, in order to enhance an effect of carrier confinement.

In this structure, the p-side electrode is formed in a lamination structure of Ti and Au, and the n-side electrode is formed with a metal layer made by alloying a lamination of Ti and Al (cf. for example PATENT DOCUMENT 1). The p-side electrode is formed through a light transmitting conductive layer such as an alloy of Ni and Au, ZnO, ITO or the like, which is formed on a surface of the laminated semiconductor layers, and the ohmic contact with the nitride semiconductor layer is obtained by the light transmitting conductive layer. On the other hand, the n-side electrode is formed directly on the exposed surface of the n-type layer by removing a part of the laminated nitride semiconductor layers and the ohmic contact is supposed to be obtained sufficiently by alloying Ti and Au. PATENT DOCUMENT 1: Japanese Patent Application Laid-Open No. HEI10-173226

### DISCLOSURE OF THE INVENTION

### Problem to be Solved by the Present Invention

As described above, a Ti—Al alloy is generally used for an n-side electrode in order to obtain an ohmic contact with a nitride semiconductor layer. But, as Al exposed on a surface is easy to be oxidized, a bonding strength deteriorates and a contact resistance increases in case of wire bonding with an Au wire or the like onto this electrode, because of existence of an oxide layer or the like, therefore an extra layer made of Au is necessary to be formed. On the other hand, since the ohmic contact with the nitride semiconductor can not be obtained sufficiently only by laminating the above-described Ti and Al layers, it becomes necessary to sinter after laminating in order to diffuse Al into the nitride semiconductor sufficiently, and Ti and Al make an alloy too at the time of sintering. At this sintering, as Ti, Al and Au make an alloy if an Au layer is already formed, it becomes useless to form the Au layer because a part of alloyed Al is exposed on the surface. Then, as it is necessary to form a Ti/Au layer or an Au layer further after sintering a Ti layer and an Al layer after laminating them, there rises a problem such that a manufacturing process becomes complicated because a depositing process of layer(s) should be applied twice.

Further, the present inventors examined earnestly and repeatedly to prevent an operation voltage from rising caused by an influence of the contact resistance or the like between the electrode and the nitride semiconductor layer. As a result of this, it was found that the contact resistance is small when the Ti layer is formed in a determined thickness of approximately 10 nm in case of the Ti—Al alloy, and that rising of the operation voltage does not matter very much. And it was found that, even a small increase of a thickness of the Ti layer makes the contact resistance rise remarkably and that the operation voltage rises easily by approximately 0.1 V.

The present invention is directed to solve the above-described problems and an object of the present invention is to provide a semiconductor light emitting device having an n-side electrode of a structure in which a contact resistance between the n-side electrode and a nitride semiconductor layer can be reduced stably.

Another object of the present invention is to provide a semiconductor light emitting device having an n-side electrode in which an ohmic contact with a nitride semiconductor layer can be obtained with a simple manufacturing process and in which an Au layer is formed on a surface thereof in order to make wire bonding easy, and to provide a method for manufacturing the same.

### Means for Solving the Problem

The present inventors examined earnestly and repeatedly to lower a driving voltage of the nitride semiconductor light emitting device and found that a contact resistance increases in case that the Ti layer is a little thicker in the Ti—Al alloy layer used as the n-side electrode by the prior art as described above, and that the driving voltage rises. It was also found that: a layer made of a single Al makes no problem in an adhesion property by alloying with being sufficiently diffused into the nitride semiconductor layer by a heat treatment, although Ti is used for increasing the adhesion property with the nitride semiconductor layer in the prior art; from an aspect of a contact resistance, the contact resistance between Al and the nitride semiconductor is further smaller than that between Ti and the nitride semiconductor; and a connection can be achieved without rising of the driving voltage.

A semiconductor light emitting device according to the present invention includes: a substrate; a semiconductor lamination portion provided on the substrate, the semiconductor lamination portion including an n-type layer and a p-type layer which are made of a nitride semiconductor; and an n-side electrode and a p-side electrode connected electrically to the n-type and p-type layers respectively, wherein the n-side electrode is formed so as to contact directly with the n-type layer made of the nitride semiconductor and includes a metal layer made of an Al which is on a side in contact with the n-type layer made of the nitride semiconductor layer.

Here, the nitride semiconductor means a semiconductor composed of a compound (nitride) of Ga of group III element and N of group V element or a compound in which a part or whole of Ga of group III element is substituted by other element of group III element like Al, In or the like and/or a part of N of group V element is substituted by other element of group V element like P, As or the like.

The Al of the n-side electrode is provided so as to form an ohmic contact with the nitride semiconductor layer by diffusing a part of the Al into the nitride semiconductor layer.

It is preferable that, an Au layer is provided as a top surface on a surface of the Al layer through a barrier metal layer made of a metal having a higher melting temperature than that of the Al, since the Au and Al layers on the surface of the electrode can not be alloyed each other even by the heat treatment because they are separated by the barrier metal layer, and the Au layer excellent in wire bonding can be ensured on the surface while keeping the ohmic contact between the nitride semiconductor and the metal layer by diffusing Al into the nitride semiconductor sufficiently. As a result, the heat treatment can be performed after forming these metal layers in series to obtain the ohmic contact with the nitride semiconductor layer.

Concretely, the n-type layer made of the nitride semiconductor provided with the n-side electrode is made of AlₓGa₁₋ₓN(0≦x≦0.5) and the barrier metal layer is made of at least one metal selected from a group of Ni, Pt, V, Cr, Mo, Al and Ti. More concretely, the n-side electrode is formed in each lamination structure of Al/Ni/Au, Al/Pt/Au or Al/Mo/Au, laminated from a side of the n-type layer made of the nitride semiconductor.

Even in a structure in which the substrate is made of a nitride semiconductor and the n-side electrode is formed on a back surface of the substrate such that a metal layer contacted to the substrate is made of Al, the contact resistance of die bonding can be also reduced while obtaining the ohmic contact between the semiconductor layer and the metal layer.

A method for manufacturing a semiconductor light emitting device according to the present invention includes steps of; growing a semiconductor lamination portion including an n-type layer and a p-type layer which are made of a nitride semiconductor on a substrate, and forming an n-side electrode on an exposed surface which is at least a part of the n-type layer exposed by etching, or on a back surface of the substrate made of an n-type nitride, wherein an Al layer, a barrier metal layer and an Au layer are laminated in this order on the exposed surface of the n-type layer or on the back surface of the substrate, and wherein the Au layer is made leave on the surface, while diffusing a part of an Al of the Al layer into the n-type layer made of the nitride semiconductor or into the back surface of the substrate by a heat treatment.

### EFFECT OF THE INVENTION

By the present invention, since the Al layer is formed as one side of the n-side electrode, which is a side connected to the n-type layer made of the nitride semiconductor, the contact resistance with the nitride semiconductor layer is significantly smaller than that with Ti and the n-side electrode in which a driving voltage is not raised can be formed.

Since the barrier metal layer made of a material having a higher melting temperature than that of Al is formed, while the Au layer is formed on the surface through a barrier metal layer to improve adhesion property of wire bonding, the Au layer on the surface is not damaged even in the heat treatment for obtaining the ohmic contact of the Al layer and the nitride semiconductor layer after forming all of metal layers for the n-side electrode, because the barrier metal layer can prevent the Al layer and the Au layer from alloying. Then, the Au layer can be left on the surface of the metal layers as it is, while the ohmic contact can be obtained by diffusing Al into the nitride semiconductor layer by sintering (heat treatment). With a simple process, an electrical connection with a gold wire or the like for wire bonding can be performed surely and with a low contact resistance, and consequently, an electrical connection with the nitride semiconductor layer can be performed in a remarkably low resistance.

### BRIEF DESCRIPTION OF THE DRAWINGS

FIG. 1 is a cross-sectional view explaining an embodiment of the semiconductor light emitting device according to the present invention.

FIGS. 2A to 2C are figures explaining a principle of a transfer length method (TLM) used in a study on a material of the n-side electrode according to the present invention.

FIG. 3 is a figure showing a relationship between a distance between both electrodes and a resistance between both electrodes used in seeking for the contact resistance between the n-type layer made of a nitride semiconductor and the Al electrode according to the present invention.

FIGS. 4A and 4B are cross-sectional views explaining other example of a structure of the n-side electrode shown in FIG. 1.

FIG. 5 is a cross-sectional view explaining other embodiment of the semiconductor light emitting device according to the present invention.

### EXPLANATION OF LTTERS AND NUMERALS

1: substrate
4: n-type layer
5: super lattice layer
6: active layer
7: p-type layer
8: p-type contact layer
9: light transmitting conductive layer
10: p-side electrode
11: n-side electrode
11a: Al layer
11b: barrier metal layer
11c: Au layer

### THE BEST EMBODIMENT OF THE PRESENT INVENTION

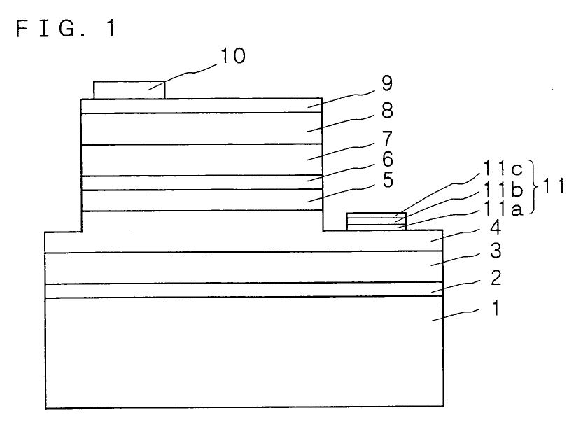

An explanation will be given below of a semiconductor light emitting device according to the present invention in reference to the drawings. In FIG. 1, there is shown a cross-sectional view explaining an embodiment of the semiconductor light emitting device according to the present invention, in which nitride semiconductor layers suitable for emitting a blue type light are laminated on a sapphire substrate.

As shown in FIG. 1, in the semiconductor light emitting device according to the present invention, semiconductor layers 2 to 8 to form a light emitting layer are laminated on a surface of a substrate 1 made of, for example, a sapphire (Al₂O₃ single crystal) or the like and a p-side electrode 10 is formed on the surface thereof thorough a light transmitting conductive layer 9. An n-side electrode 11 is formed on an exposed surface of an n-type layer 4, exposed by removing a part of the semiconductor layers 4 to 8 by etching. The present invention is characterized in that a side of the n-type electrode in contact with the n-type layer is composed of an Al layer 11a as described later. It is preferable that the n-side electrode includes actually the Al layer 11a in contact with the n-type layer, a barrier metal layer 11b and an Au layer 11c.

The Al layer 11a is provided as a layer to make an ohmic contact with the nitride semiconductor layer and it is formed so as to obtain the ohmic contact by diffusing a part of the Al into the nitride semiconductor layer sufficiently by applying a heat treatment at a rapid thermal annealing (RTA) which is performed in an atmosphere of nitrogen, at a temperature of approximately 300 to 700° C., for example of approximately 625° C., and for a period of approximately 1 to 30 sec, for example of approximately 5 sec, after forming layers. This heat treatment may be applied not only to a single status of the Al layer 11a formed alone, but also to a status after forming the barrier metal layer 11b and the Au layer 11c subsequently. The Al layer 11a is formed approximately 0.01 to 10 μm thick, preferably approximately 0.2 to 1 μm thick, for example approximately 0.25 μm thick.

The barrier metal layer 11b is formed in order to make the Al layer 11a and the Au layer 11c formed on the surface exist independently not to make an alloy in the heat treatment, and a metal having a higher melting temperature than that of the Al, such as Ni, V, Cr, Mo, Ti or the like is employed. Since the barrier metal layer 11b is a layer to separate the Al layer 11a and the Au layer 11c not to make an alloy, it is formed approximately 0.05 to 0.5 μm thick, preferably approximately 0.1 to 0.2 μm thick. Also, since the Au layer 11c is a layer to improve a property of wire bonding and to ensure wire bonding, it is formed approximately 0.1 to 10 μm thick, preferably approximately 0.2 to 3 μm thick.

A reason why the Al layer 11a is formed on a side of the n-type electrode in contact with the n-type layer made of the nitride semiconductor layer will be described in detail below. The present inventors examined earnestly and repeatedly to lower a driving voltage of the nitride semiconductor light emitting device as described above, and found that even a Ti—Al alloy layer is used as the n-type electrode, the contact resistance between the n-type electrode and the nitride semiconductor layer can not be always lowered sufficiently when Ti layer is formed thick. As a result of further examination, it was found that by forming an Al layer as the metal layer which contacts with the nitride semiconductor layer, the contact resistance can be surely lowered and the driving voltage can be also lowered without any problems of adhesion property between the n-type electrode and the nitride semiconductor layer.

The present inventors examined earnestly and repeatedly to solve problems such as inconvenience and increasing of production manhours in the prior art where in forming the n-side electrode connected to the n-type layer made of the nitride semiconductor, it is necessary to form a Ti/Al layer and a Ti/Au layer by processes of two times and separately in order to obtain an Au layer suitable for wire bonding on the surface of the n-side electrode while raising an ohmic contact with a nitride semiconductor layer sufficiently. As a result of this examination, it was found that, by making a lamination structure of an Al layer, a barrier metal layer and an Au layer, and by applying a heat treatment for obtaining the ohmic contact with a nitride semiconductor layer, the n-side electrode can be easily formed with remarkably small contact resistance because the contact resistance with the nitride semiconductor layer can be reduced and because the Au layer on the surface, on which wire bonding is operated excellently, can be maintained without making alloys.

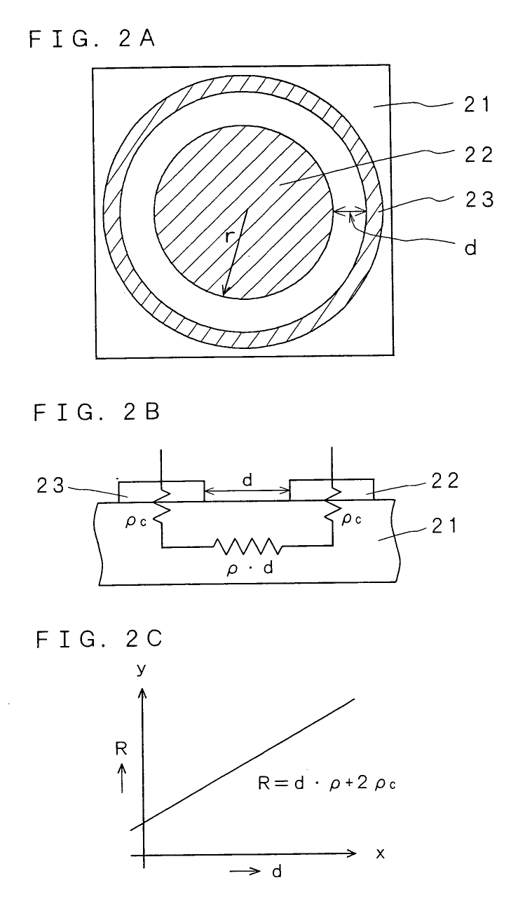

Namely, layers made of various metals are firstly formed on the n-type layer made of the nitride semiconductor and their contact resistances are evaluated. The evaluation of the contact resistance is performed by measuring the contact resistance by a transfer length method (TLM). A principle of the TLM is explained by figures shown in FIGS. 2A to 2C. Namely, as shown in FIG. 2A, a resistance R between both electrodes is measured by a voltage applied between both electrodes 22 and 23 and by an electric current, by forming circular electrodes 22 and 23 on a surface of a nitride semiconductor layer 21. The electrodes 22 and 23 are formed so that, the second electrode 23 of a ring shape is formed around the first electrode 22 of a circle shape having a diameter r (for example, approximately 100 μm) through a certain distance d. The resistance R(R=ρ×d+2ρ_{c}) between both electrodes 22 and 23, as shown in FIG. 2B, is composed of a sheet resistance of the semiconductor layer 21, ρ (resistance per unit length)×d, and the contact resistance 2ρ_{c}. By measuring the resistance between both electrodes 22 and 23 while varying the distance d, it is observed that the resistance R measured increases as the distance d between both electrodes 22 and 23 increases as shown in FIG. 2C. Therefore, when the d is zero, a value of intersection of a y-axis is a value of the contact resistance 2ρ_{c}.

The nitride semiconductor layer 21 is formed as an n-type GaN layer by doping Si of approximately 4×10¹⁸ cm⁻³ and approximately 10 μm thick, and material and thickness of the electrodes 22 and 23 on the surface thereof is varied as described later. In any cases, measurement was operated after obtaining the ohmic contact by applying a RTA (rapid thermal annealing) treatment in an atmosphere flowing nitrogen of 1 litter per second, at a temperature of 625° C., and for 5 seconds, after forming layers of materials for the electrode.

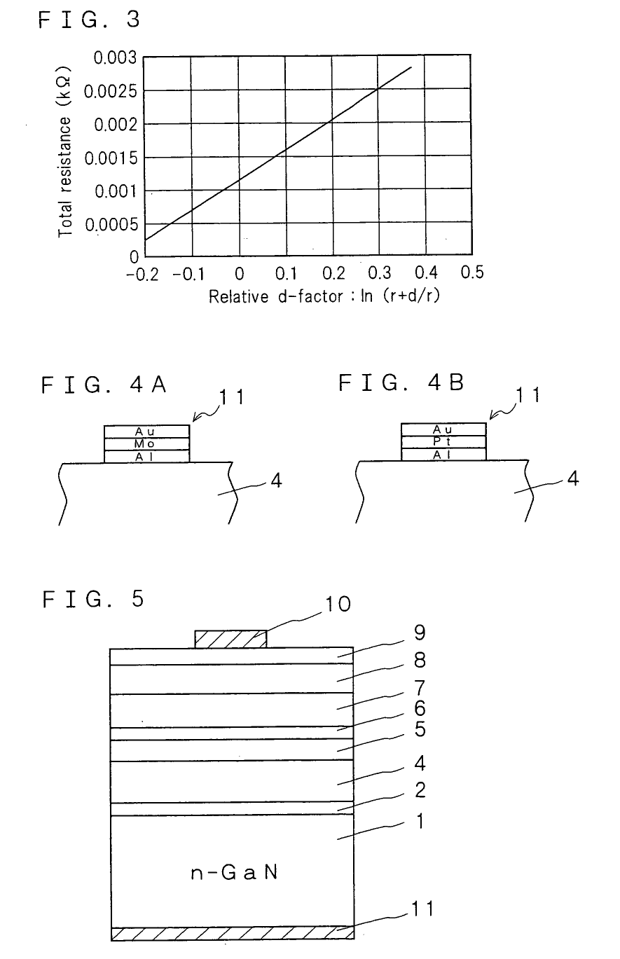

At first, a result of measuring the resistance with varying the distance d between both electrodes in case of forming an Al layer 250 nm thick is shown in FIG. 3. In FIG. 3, a relative d-factor is represented by natural logarithm ln(r+d/r) as an x-axis. Here, r represents the radius of the electrode 22 and d, the distance between both electrodes. In this graph, y=4.571×10⁻³ x+1.128×10⁻³, the contact resistance is given by 7.42×10⁻⁵ Ωcm².

In the same manner, there were examined the contact resistance of a Ti—Al alloy layer formed by laminating a Ti layer of 10 nm thick and an Al layer of 250 nm thick and by applying a heat treatment, the contact resistance of a Ti layer of 200 nm thick, and the contact resistance of a Ti—Au alloy layer by laminating a Ti layer of 10 nm thick and an Au layer of 250 nm thick and by applying the heat treatment, which are used in the prior art. Arranged results are shown in Table 1.

Table 1

TABLE 1
contact resistance to electrode material

| electrode | contact resistance |
|---|---|
| material | (Ωcm²) |
| Al | 7.42 × 10⁻⁵ |
| Ti—Al | 7.52 × 10⁻⁵ |
| Ti | 1.38 × 10⁻³ |
| Ti—Au | 2.16 × 10⁻³ |

Subsequently, an influence of the contact resistance to the driving voltage was examined. An area S of the electrode of the diameter of 100 μm is 7.85×10⁻⁵ cm². The resistance R in this case was R=ρ_{c}/S=7.42×10⁻⁵/7.85×10⁻⁵=0.945Ω. Accordingly, an increasing of voltage is 0.945×20 mA=18.9 mV at the driving current 20 mA. Since a driving voltage of LEDs of this kind is generally approximately 3.2 to 3.5 V, and an increasing of the driving voltage is necessary to be 0.15 V or less at the driving current 20 mA, the contact resistance of the Al layer and the Al—Ti layer described above is supposed not to influence an increasing of the driving voltage. But, the contact resistance of Ti makes a problem because of the contact resistance of 100 times. The contact resistance is necessary to be 5.9×10⁻⁴ Ωcm² or less by calculating backward from a limit 0.15 V of increasing driving voltage. From this point of view, the Ti—Al layer used in the prior art does not matter in increasing of the driving voltage because the contact resistance is near that of the Al layer according to the present invention. But, since the Ti layer which may have a very high contact resistance is formed on a side of the nitride semiconductor layer, it is obvious, from the contact resistance of Ti, that the contact resistance increases when a mass of this layer is large, therefore, the contact resistance may increase depending upon a manufacturing condition and is lacking in stability.

On the other hand, samples were prepared by forming a laminating a Ni layer of 50 nm thick and an Au layer of 300 nm thick on a Al layer of 250 nm thick, and by wire bonding, and 50 samples were inspected to examine occurrence of wire bonding peeling (peeling of the electrode at a wire bonding part). As a result of this, no defect was observed and no problem was recognized in adhesion between the electrode and the nitride semiconductor layer. As the inspection was operated after examining the contact resistance after the heat treatment was applied, then the Ni layer and the Au layer was laminated thereon. In case of manufacturing actual LEDs, the Al layer, the Ni layer and the Au layer are laminated continuously, thereafter the heat treatment may be applied to obtain the ohmic contact. A barrier metal layer made of Ni or the like having a higher melting temperature than that of Al is interposed in order to prevent the Au layer on the surface and the Al layer from making an alloy, even if the heat treatment is applied after laminating the metal layers.

Subsequently, a structure of the semiconductor lighting device shown in FIG. 1 will be described in detail. Semiconductor layers laminated on the sapphire substrate 1 are composed of: a low temperature buffer layer 2 made of for example GaN of approximately 0.005 to 0.1 μm thick; a high temperature buffer layer 3 made of undoped GaN of approximately 1 to 3 μm thick; the n-type layer 4 doped with Si which is a barrier layer (layer having a large band gap energy) thereon, of approximately 1 to 5 μm thick; a super lattice layer 5 formed by laminating alternately 5 to 50 pairs of for example an In_{0.02}Ga_{0.98}N layer and a GaN layer of approximately 1 to 2 nm thick respectively; an active layer 6 of a multi quantum well structure (MQW) of 0.05 to 0.3 μm thick, formed by laminating 3 to 8 pairs of a well layer made of a material having a smaller band gap energy than that of the barrier layer and of 1 to 3 nm thick, and a barrier layer made of GaN of 10 to 20 nm thick; a p-type barrier layer (layer having a large band gap energy) 7 made of a p-type AlGaN based compound semiconductor layer; and a p-type contact layer 8 made of p-type GaN of 0.1 to 2 μm thick in total with the p-type barrier layer 7, by laminating in this order.

A reason why the high temperature buffer layer 3 is undoped is that a first layer grown at a high temperature is preferable for improving a property of a crystal of the nitride semiconductor layer laminated, however, an undoped material is not employed in case of a conductive substrate. In addition, although the p-type layer 7 and the contact layer 8 are preferable to contain Al on a side of the active layer 6 from a view point of carrier confinement, a layer made of GaN alone may be used. Further, double layers may be formed by adding an AlGaN based compound semiconductor layer to the n-type layer 4, and these layers can be replaced by other nitride semiconductor layer. In this example, a structure of a double hetero junction by sandwiching the active layer 6 with the n-type layer 4 and the p-type layer 7 is described, but a structure of a p-n junction by joining the n-type layer and the p-type layer directly, may be used. Although the p-type AlGaN based compound semiconductor layer is grown directly on the active layer 6, it is preferable to grow an undoped AlGaN based compound semiconductor layer of approximately several nanometers because a leakage caused by contact of the p-type layer and the n-type layer can be prevented while filling pits occurred in the active layer. Generally, the n-type layer and the p-type layer including contact layers can be composed of AlₓGa₁₋ₓN (0≦x≦0.5), and a semiconductor lamination portion may be formed with the n-type layer and the p-type layer so as to form a light emitting layer.

A light transmitting conductive layer 9 made of for example ZnO is formed approximately 0.1 to 10 μm thick on the semiconductor lamination portion and the p-side electrode 10 is formed with a lamination structure of Ti and Au on a part thereof. The n-side electrode 11, which is formed in a lamination structure of Al, Ni and Au, is formed on a surface of the n-type layer 4 which is exposed by removing a part of the semiconductor lamination portion by etching. An Al layer 11a is laminated 10 nm to 10 μm thick, for example 0.1 μm thick, a barrier metal layer 11b of Ni layer, 30 to 100 nm thick, for example, 50 nm thick, and an Au layer 11c, approximately 0.2 to 1 μm thick, for example 0.25 μm thick. Although the heat treatment of the rapid thermal annealing (RTA) is applied at a temperature of approximately 600° C. for approximately 5 seconds, each metal layer makes no alloy because of the barrier metal layer 11b of Ni layer and the Au layer 11c can be obtained on a surface of the n-side electrode without making an alloy, even a part of the Al layer diffuses into the nitride semiconductor, thereby a bonding property can be improved while wire bonding. A passivation layer, not shown in figures, made of SiO₂ or the like is formed on the whole surface except the surface of the p-side electrode 10 and the n-side electrode 11. The light transmitting conductive layer 9 is not limited to ZnO. An ITO or a thin alloy layer of Ni and Au of approximately 2 to 100 nm thick can also transmits light and diffuses current in an entire chip.

By the present invention, as an Al layer is provided as a layer of the n-side electrode 11 of the semiconductor light emitting device which is in contact with the nitride semiconductor layer, the contact resistance can be lowered significantly. Further, only by laminating layers of Al, Ni and Au continuously at a depositing process of one time and applying the heat treatment, the ohmic contact between the electrode and the semiconductor layer can be obtained, and moreover, wire bonding can be achieved with a good result by preventing the electrode from a pollution such as oxidation or the like because the Al is not exposed at the surface. As a result, as connection with an external lead can be obtained with a very small contact resistance, a driving voltage can be maintained to be low when an emitting device is formed, and an excellent emitting device having very high internal quantum efficiency can be obtained.

Subsequently, an explanation will be given below of a method for manufacturing the semiconductor light emitting device shown in FIG. 1. Semiconductor layers are grown in order, by using a metal organic compound vapor deposition (MOCVD) method in which, with H₂ as a carrier gas, necessary gasses are supplied such as trimethyl gallium (TMG), ammonia (NH₃), trimethyl aluminum (TMA), trimethyl indium (TMIn) or the like as a reactant gas, SiH₄ as an n-type dopant gas, and biscyclopentadienyl magnesium (Cp₂Mg), dimethyl zinc (DMZn) or the like as a p-type dopant gas.

Firstly, the low temperature buffer layer 2 made of GaN layer is formed approximately 0.005 to 0.1 μm thick at a low temperature of for example approximately 400 to 600° C., on the insulating substrate 1 made of for example sapphire. Subsequently, the high temperature buffer layer 3 made of an undoped GaN layer is formed approximately 1 to 3 μm thick, and the n-type layer (barrier layer) 4 made of n-type GaN doped with Si is formed approximately 1 to 5 μm thick, at a raised temperature of for example approximately 600 to 1,200° C.

Thereafter, with lowering the growth temperature to a low temperature of 400 to 600° C., the super lattice layer 5 of a super lattice structure is formed by laminating 5 to 40 pairs of an In_{0.02}Ga_{0.98}N layer and a GaN layer, both of approximately 1 to 2 nm thick, alternately, and the active layer 6 of a multi quantum well structure (MQW) is formed 0.05 to 0.3 μm thick, by laminating 3 to 8 pairs of a well layer made of In_{0.13}Ga_{0.87}N of approximately 1 to 3 nm thick and a barrier layer made of GaN of approximately 10 to 20 nm thick, alternately.

With raising a temperature of inside of the growth equipment to 600 to 1200° C., the p-type layer 7 made of AlGaN based compound semiconductor of approximately 0.1 to 0.5 μm thick, and a contact layer 8 made of a p-type GaN of approximately 0.1 to 0.5 um thick are laminated respectively.

Thereafter, an annealing at a temperature of 400 to 800° C. and for 10 to 60 minutes is operated in order to activate the p-type dopant after forming a protective layer made of SiN or the like on the surface, and the light transmitting conductive layer 9 is formed 0.1 to 10 μm thick by forming a ZnO layer by an MBE technique, a sputtering technique, an evaporating technique, a PLD technique, an ion plating technique or the like. Subsequently, a part of the semiconductor layers laminated is etched by a reactive ion etching with chlorine gas or the like so as to expose the n-type layer 4 in order to form the n-side electrode 9.

Then, Al of approximately 0.1 μm thick, Ni of approximately 50 nm thick and Au of approximately 250 nm thick are continuously deposited respectively on the surface of the n-type layer by a sputtering technique or an evaporating technique, and the heat treatment is applied by an RTA method at a temperature of approximately 600° C. and for approximately 5 seconds. By using a lift-off technique for forming the n-side electrode, the n-side electrode can be formed in a predetermined shape by removing a mask. Thereafter, the p-side electrode 10 is formed by depositing Ti and Au, approximately 0.1 μm and 0.3 μm thick respectively by an evaporating technique on the light transmitting conductive layer 9 in order to form the p-side electrode. Finally, a chip of the semiconductor light emitting device shown in FIG. 1 can be obtained by dividing a wafer into chips.

In the above-described example, the structure of the n-side electrode 11 is a lamination structure of the Al layer 11a, the Ni layer (barrier metal layer 11b) and the Au layer 11c. However, although it is necessary that the Al layer is formed on a side of the nitride semiconductor layer and the Au layer is formed on a top surface, as the barrier metal layer 11b between them is not limited to Ni, a metal having a higher melting temperature than that of Al can be used. For example, as shown in FIG. 4, a structure of a small contact resistance of 5.61×10⁻⁴ Ωcm² can be obtained by laminating an Al layer of approximately 0.01 μm thick, a Mo layer of approximately 0.05 μm thick and an Au layer of approximately 0.25 μm thick respectively, and by applying a heat treatment at a temperature of 600° C. and for 5 seconds by a RTA (rapid heating), and as shown in FIG. 4B, a structure of an Al layer, a Pt layer and an Au layer can be also employed. In addition, other metals described above may be used for a barrier metal layer.

In the above-described example, since the sapphire substrate is used for the substrate on which the nitride semiconductor layers are laminated, the n-side electrode is formed on the n-type layer by exposing the n-type layer of an under layer by removing a part of the semiconductor layers laminated by etching in order to connect the n-side electrode to the n-type layer. But, it becomes not necessary to etch a part of the semiconductor layers laminated by using the GaN substrate in place of the sapphire substrate and by laminating nitride semiconductor layers thereon, because the n-side electrode can be formed directly on a back surface of the GaN substrate. An example of this case is shown in FIG. 5. In FIG. 5, although the GaN substrate is used as the substrate 1 in place of the sapphire substrate, and although an undoped high temperature buffer layer is omitted, other structure is same as the lamination structure shown in FIG. 1. And, differences are only that the n-side electrode 11 is formed on the back surface of the GaN substrate 1 by laminating the above-described metal layers of Al/Ni/Au and by applying the heat treatment, and that the p-side electrode 10 is formed near a center of a chip, then same letters and numerals are noted to same parts and explanation is omitted. Further, although the undoped GaN layer is omitted in order to lower a series resistance, a high temperature buffer layer of an n-type may be employed.

### INDUSTRIAL APPLICABILITY

According to the present invention, light emitting devices emitting blue lights, ultraviolet lights or the like, having a low driving voltage, can be obtained and can be used for a light source of a various electric apparatus such as a white light source and a white lighting and the like, a pilot lamp, a lighting apparatus, a disinfection apparatus or the like.

What is claimed is:

1. A semiconductor light emitting device comprising:
a substrate;
a semiconductor lamination portion provided on the substrate, the semiconductor lamination portion including an n-type layer and a p-type layer which are made of a nitride semiconductor; and
an n-side electrode and a p-side electrode connected electrically to the n-type and p-type layers respectively,
wherein the n-side electrode is formed so as to contact directly with the n-type layer made of the nitride semiconductor and comprises a metal layer made of an Al which is on a side in contact with the n-type layer made of the nitride semiconductor layer.

2. The semiconductor light emitting device according to claim 1, wherein the n-side electrode is formed so as to form an ohmic contact with the n-type layer made of the nitride semiconductor by diffusing a part of the Al into the n-type layer.

3. The semiconductor light emitting device according to claim 2, wherein an Au layer is formed as a top surface layer of the n-side electrode through a barrier metal layer made of a metal having a higher melting temperature than that of the Al.

4. The semiconductor light emitting device according to claim 1, wherein the n-type layer made of the nitride semiconductor provided with the n-side electrode is made of AlₓGa₁₋ₓN(0≦x≦0.5).

5. The semiconductor light emitting device according to claim 3, wherein the barrier metal layer is made of at least one metal selected from a group composed of Ni, Pt, V, Cr, Mo, Al and Ti.

6. The semiconductor light emitting device according to claim 5, wherein the n-side electrode is formed in each lamination structure of Al/Ni/Au, Al/Pt/Au or Al/Mo/Au, laminated from a side of the n-type layer made of the nitride semiconductor.

7. The semiconductor light emitting device according to claim 1, wherein the substrate is made of a nitride semiconductor, and wherein the n-side electrode is formed on a back surface of the substrate such that a metal layer contacted to the substrate is made of Al.

8. A method for manufacturing a semiconductor light emitting device comprising steps of:
growing a semiconductor lamination portion including an n-type layer and a p-type layer which are made of a nitride semiconductor on a substrate, and
forming an n-side electrode on an exposed surface which is at least a part of the n-type layer exposed by etching, or on a back surface of the substrate made of an n-type nitride,
wherein an Al layer, a barrier metal layer and an Au layer are laminated in this order on the exposed surface of the n-type layer or on the back surface of the substrate, and
wherein the Au layer is made leave on the surface, while diffusing a part of an Al of the Al layer into the n-type layer made of the nitride semiconductor or into the back surface of the substrate by a heat treatment.

9. The method for manufacturing according to claim 8, wherein the barrier metal layer is made of at least one metal selected from a group composed of Ni, Pt, V, Cr, Mo, Al and Ti.
